(19) United States
(12) Patent Application Publication
(10) Pub. No.: US 2020/0256966 A1
(43) Pub. Date: Aug. 13, 2020

(54) THERMALLY CONDUCTIVE AND ANTIFOULING BOOT FOR MARINE APPLICATIONS

(71) Applicant: BAE Systems Information and Electronic Systems Integration Inc., Nashua, NH (US)

(72) Inventors: Charles P. Wason, JR., Amherst, MA (US); Robert J. Nation, Deerfield, NH (US)

(73) Assignee: BAE Systems Information and Electronic Systems Integration Inc., Nashua, NH (US)

(21) Appl. No.: 16/270,821

(22) Filed: Feb. 8, 2019

(51) Int. Cl. G01S 7/521; H01L 41/053; H01L 41/06

(52) U.S. Cl. CPC G01S 7/521; H01L 41/06; H01L 41/0533

(57) ABSTRACT

A transducer system includes a housing having an opening, an electromechanical transducer within the housing, and an elastomeric boot over the opening. At least a portion of the elastomeric boot includes copper-comprising particles. In some applications, the copper acts as an antifouling agent and/or enhances the thermal conductivity of the elastomeric boot.

### BACKGROUND

Sonar (short for sound navigation and ranging) is a nautical tool for exploring and mapping the ocean and other large bodies of water. Sonar uses sound waves that travel quickly through water and are bounced back by large objects in the water and by the ocean floor. By determining the return time and general direction of the returning sound waves, distances to various objects or to the ocean floor topology can be calculated. Sonar utilizes one or more electromechanical transducers to convert the sound waves into electrical energy, or, in the case of active sonar, to convert electrical energy into sound waves. There are a number of non-trivial issues associated with such systems.

### BRIEF DESCRIPTION OF THE DRAWINGS

Features and advantages of embodiments of the claimed subject matter will become apparent as the following Detailed Description proceeds, and upon reference to the Drawings, in which:

FIG. 1 illustrates the use of sonar from different vessels, in accordance with some embodiments of the present disclosure.

FIG. 2 illustrates an example electromechanical transducer, in accordance with an embodiment of the present disclosure.

FIG. 3 illustrates a view of a transducer system using a boot, in accordance with an embodiment of the present disclosure.

FIG. 4A illustrates a top-down view of a transducer system, according to an embodiment. FIG. 4B illustrates the transducer system of FIG. 4A having a boot (e.g., a waterproof seal) stretched across an opening of the system.

FIG. 5 illustrates an example of a boot having a bilaminar construction, according to an embodiment.

FIG. 6 illustrates the boot shown in FIG. 5, with an inner layer being added over first layer to provide further corrosion resistance, according to an embodiment.

FIG. 7 illustrates another example of boot having a multilayer configuration, according to an embodiment.

Although the following Detailed Description will proceed with reference being made to illustrative embodiments, many alternatives, modifications, and variations thereof will be apparent in light of this disclosure.

### DETAILED DESCRIPTION

Structures are disclosed that provide environmental protection and thermal management for electromechanical transducers, such as those used in a sonar array. Some sonar transducers require a boot, or a waterproofing seal to protect the transducer from electrical shorting in the water. In an embodiment, a transducer system includes a housing having an opening, an electromechanical transducer within the housing, and an elastomeric boot across or otherwise over the opening. At least a portion of a thickness of the elastomeric boot includes copper-comprising particles. In particular, and according to some such embodiments, the inclusion of copper-comprising particles in a portion of the boot provides multiple advantages to the operation of the transducer system. The waterproofing seals (such as the boot) are prone to fouling from marine organism growth. This fouling can adversely impact the performance of the sonar. The copper acts as an antifouling agent and prevents biofilms and other marine growths from accumulating on the boot when exposed to a body of water, or any other liquid. Additionally, copper is highly thermally conductive, and the presence of the copper-containing particles aids in the extraction of heat generated from the electromechanical transducer within the housing. These and other advantages are discussed herein in more detail. Numerous embodiments, variations, and applications will be appreciated.

Biofouling describes the accumulation of microorganisms, plants, algae, or animals on wetted surfaces. Antifouling is the ability of specifically designed materials and coatings to remove or prevent biofouling on wetted surfaces. Marine biofouling usually occurs over four stages of ecosystem development. The first stage involves biofilm formation where van der Waals interaction causes a submerged surface to be covered with a conditioning film of organic polymers. In the second stage, the film of organic polymers allows the process of bacterial adhesion to occur, with both diatoms and bacteria (e.g., Vibrio alginolyticus, Pseudomonas putrefaciens, etc.) attaching, thereby initiating the formation of a biofilm. In the third stage, the rich nutrients and ease of attachment into the biofilm allow secondary colonizers of spores of macroalgae (e.g., Enteromorpha intestinalis, ulothrix, etc.) and protozoans (e.g., vorticella, zoothamnium sp., etc.) to attach themselves. In the fourth and final stage, tertiary colonizers, sometimes called macrofoulers, have attached. Macrofoulers include, for instance, tunicates, mollusks, and sessile Cnidarians.

General Overview

As previously noted, there are a number of issues with sonar systems, particularly those that run in a continuous mode. In more detail, the transducers used in sonar systems can generate varying degrees of heat over a given period. The heat output becomes greater as the transmission power and duty cycle increases for active sonar systems. If too much heat is generated, it may degrade the performance of the transducer or the boot and decrease its lifetime. Sonar transducers typically operate at a duty cycle of around 10%-20% when generating the sound waves. However, bringing duty cycles closer to continuous operation, such as around 50%, around 75%, or around 100%, can be desirable for certain applications. At these higher duty cycles, the electromechanical transducers tend to heat up faster and the performance and life span can suffer. Additionally, sonar systems are typically placed within a body of water (such as an ocean) and may remain in contact with the water for a long period of time. Biofilms and other marine or fungal growths may accumulate on the systems, thus degrading their performance.

Thus, and in accordance with an embodiment of the present disclosure, a system is provided that includes an elastomeric boot stretched over or otherwise fitted to a portion of a housing that contains the sensitive sonar transducers. The elastomeric nature of the boot allows it to mechanically deflect as necessary for sending or receiving the sonar waves. Additionally, the boot's elasticity provides a leak-proof seal to prevent any water from entering the housing. According to some embodiments, at least a portion of the boot includes copper-containing particles that serve a dual-purpose of both enhancing the thermal conductivity of the boot and increasing the boot's antifouling properties.

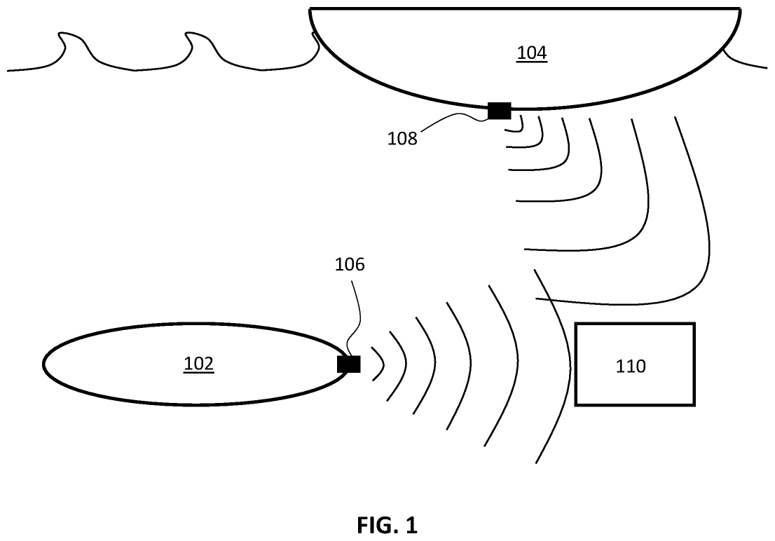

FIG. 1 illustrates the use of sonar to detect an object under the water, according to some embodiments. For example, an underwater vessel 102 can include a transducer array 106 to generate sound waves directed out into the water. Underwater vessel 102 can be a submarine or any other underwater vehicle (including one-man propulsion systems and unmanned vehicles) designed to operate under the water's surface. The transducer array may also be stationary and used to detect underwater activity in a region, wherein multiple transducer arrays can be used to detect underwater activity across a large region. Transducer array 106 can include any number of electromechanical transducers to generate or receive sound waves. Transducer array 106 may be protected by an elastomeric boot, as discussed in some embodiments herein.

Transducer array 106 produces sound waves that can bounce off an object 110 under the water. Object 110 may be a sea creature, another submarine or other underwater vessel, a large rock or underwater topography (e.g., reef), or any other physical thing large enough to reflect the generated sound waves. In some examples, object 110 represents the ocean floor.

In some examples, a boat 104 on the surface of the water can also include a transducer array 108 attached to an underside of the hull in the water. Transducer array 108 can be substantially similar to transducer array 106 and can also be protected by an elastomeric boot, as discussed in some embodiments herein.

In still other embodiments, rather than a vessel 102, the transducer array 106 may be included in a non-moving fixture or housing that is placed in the water at a generally fixed location, whether sitting on the floor of the ocean (or other body of water) or suspended in the water by one or more non-moving flotation devices. In one such embodiment, the transducer array 106 can be placed on the floor of the water body, near an intake pipe for a hydroelectric power plant. In such cases, the transducer array 106 can be used for fish mitigation (e.g., discouraging fish from swimming near the intake).

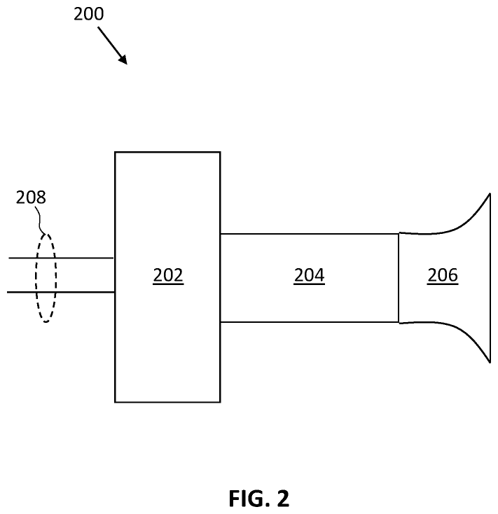

FIG. 2 illustrates an example of an electromechanical transducer 200, according to an embodiment. Electromechanical transducer 200 may be used in a sonar system to generate or receive sound waves. Electromechanical transducer 200 may be used in other applications that use sound, such as for generating or receiving seismic waves or for simple acoustic devices such as speakers and microphones.

Electromechanical transducer 200 includes a tail mass 202, a transducer region 204, and a head mass 206. Electrical connections 208 may also be provided to transducer region 204 of electromechanical transducer 200. Tail mass 202 may be a solid metal material, such as steel, and head mass 206 may be a lighter metal material, such as aluminum, although any number of materials can be used for the tail mass 202 and head mass 206, including non-metals (e.g., plastics such as poly vinyl chloride and composites). Depending on the application, and according to some embodiments, head mass 206 and tail mass 202 may each be any material if head mass 206 is lighter than tail mass 202. By ensuring that head mass 206 is lighter than tail mass 202, head mass 206 will vibrate at a greater amplitude compared to tail mass 202 and can generate high-intensity sound waves. Other configurations will be appreciated in light of this disclosure, including those that simply include the transducer array without one or either of the tail mass 202 and head mass 206. Although FIG. 2 illustrates a tonpiltz style transducer, any other transducer structure may be used, such as, for example, a flextensional transducer or a barrel stave transducer.

Transducer region 204 acts like a spring between head mass 206 and tail mass 202, and includes a piezoelectric ceramic material, according to an embodiment. Examples of piezoelectric ceramic materials include barium titinate or lead zirconate titanate. Such materials produce an electric charge when a mechanical stress is applied and vice versa. In some embodiments, transducer region 204 includes one or more piezoelectric crystals such as quartz, Rochelle salt, or ammonium dihydrogen phosphate. In some embodiments, transducer region 204 includes one or more magnetostrictive materials that expand or contract in response to a magnetic field. In a more general sense, any number of transducer mechanisms can be used to implement the transducer region 204.

When used for sonar, electromechanical transducer 200 may be encapsulated in a waterproof housing, and head mass 206 is acoustically coupled to the water. When used as a transmitter, an oscillating electrical voltage is connected across electrodes of transducer region 204 via electrical connections 208 causing transducer region 204 to alternately lengthen and contract. This in turn causes head mass 206, which is acoustically coupled to the water, to vibrate large amplitudes and produce a sound pressure wave. As a receiver, a sound pressure wave pushes head mass 206, causing transducer region 204 to vibrate. This causes the length of the piezoelectric ceramic material to alternately contract and expand, which generates a voltage across transducer region 204. The generated voltage can be measured out with electrical connections 208.

As transducer region 204 converts the electrical energy into mechanical movement, it also releases heat. More heat is released as the duty cycle (duration for which power is applied to the electrodes of transducer region) increases, thus limiting how much electromechanical transducer 200 can be driven if the heat is not compensated for in some way.

Thermally Conductive/Antifouling Boot

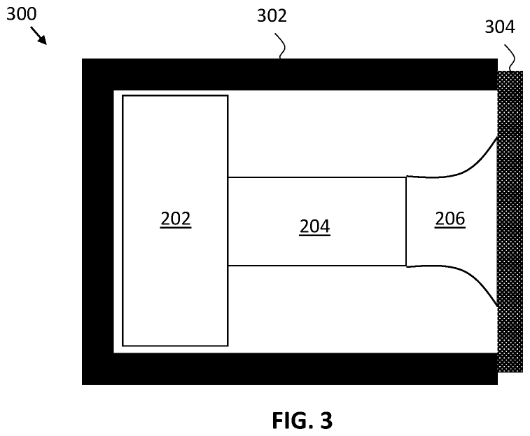

FIG. 3 illustrates a view of a transducer system 300, according to some embodiments. Transducer system 300 includes a housing 302 around an electrochemical transducer with tail mass 202, transducer region 204, and head mass 206 as discussed above in FIG. 2. In some embodiments, one wall of housing 302 is replaced by an elastomeric boot 304. Boot 304 may include rubber or some other polymer material. The elasticity of boot 304 allows it to vibrate along with head mass 206, but also allows it to seal the interior of housing 302. In some embodiments, boot 304 includes an interior wall facing into housing 302 and an exterior wall in contact with water during operation of transducer system 300. Housing 302 may be any metal material, such as aluminum, or any plastic. In some embodiments, housing 302 is a material that is chosen for having a relatively high thermal conductivity, to further aid in heat dissipation.

In some embodiments, boot 304 is made of a synthetic rubber material with a bilaminar construction. The synthetic rubber may be ethylene propylene diene monomer (EPDM) rubber. Each of the two layers in the bilaminar construction may include a same base rubber material with various concentrations ranging from 0%-30% by weight of other materials added to increase conductivity and/or reducing bio-fouling. These added materials may include metal particles intermixed with the rubber material. The metal particles may be copper-comprising particles, such as cuprous oxide. In some other embodiments, boot 304 is made of multiple (e.g., more than 2) synthetic rubber layers, each of which can have various concentrations of other added materials. In other embodiments, boot 304 is made of a single material layer having a base rubber material with an added concentration by weight of other materials.

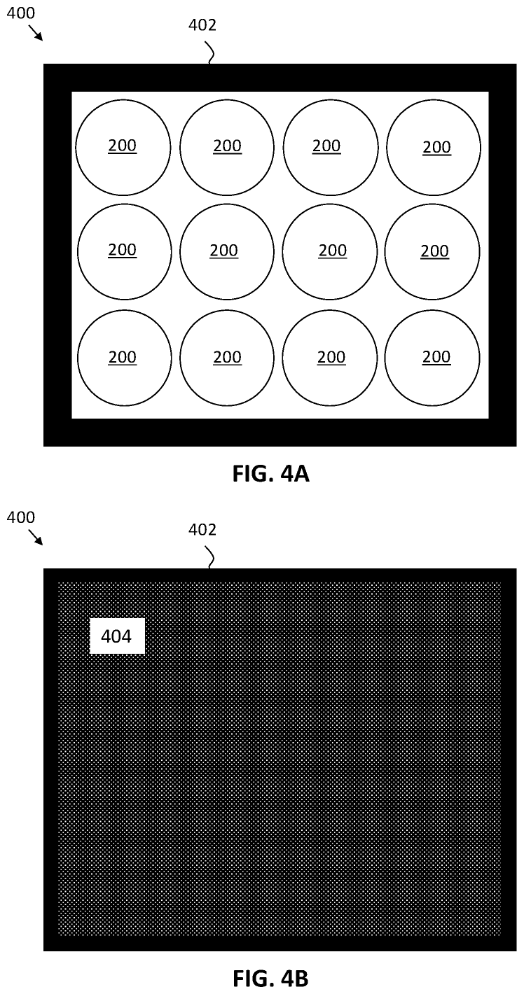

FIG. 4A illustrates a top-down view of another transducer system 400 that includes a plurality of electromechanical transducers 200 arranged within a housing 402, according to an embodiment. Housing 402 may be any metal material, such as aluminum. Housing 402 has an opening, for example in the plane of the page, where a boot extends across to seal the opening and provide environmental protection of electromechanical transducers 200. In the top-down view of FIG. 4A, the boot has been removed for clarity. FIG. 4B illustrates transducer system 400 having a boot 404 stretched across the opening.

Boot 404 may have the same physical and chemical properties of boot 304 described above with reference to FIG. 3. In some embodiments, boot 404 is a single element that stretches across one large opening in housing 402. In some other embodiments, boot 404 includes multiple smaller boot segments that stretch over smaller openings arranged over corresponding electromechanical transducers 200. The smaller boot segments may have different properties from one another (e.g., different number of layers and/or different concentrations of metal particles.)

Any number of electromechanical transducers 200 may be included in housing 402, whether one, two, three, . . . , ten, twenty, etc. Furthermore, the plurality of electromechanical transducers 200 may be arranged in any pattern within housing 402, or even randomly placed in some cases. Various ones of the plurality of electromechanical transducers 200 may be different sizes to produce sound waves having different frequencies or amplitudes, thereby providing a broader spectrums of sound waves. Electrical connection may be made to each of electromechanical transducers 200 such that they operate in unison, or individual electrical connection may be made to one or more of the electromechanical transducers 200 such that they can operate independently from one another.

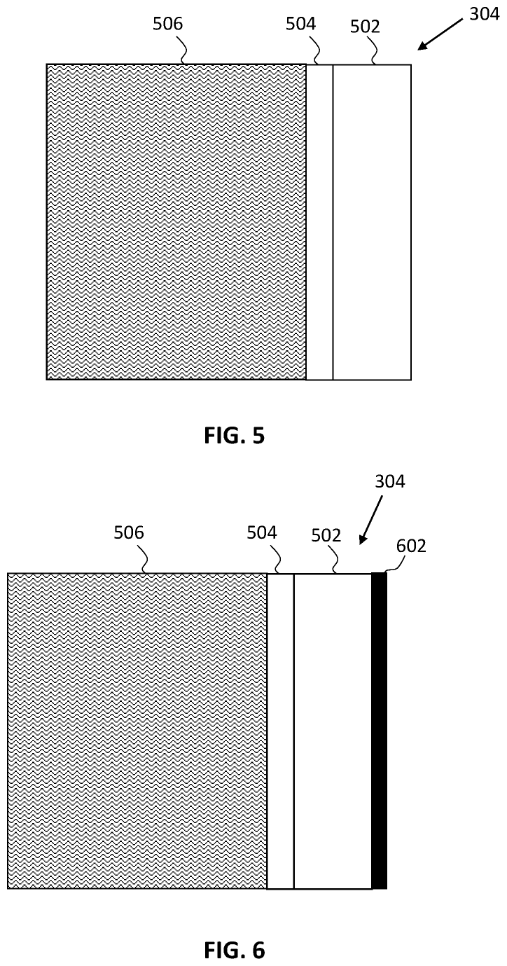

FIG. 5 illustrates an example of boot 304 having a bilaminar construction, according to an embodiment. Boot 304 includes a first layer 502 and a thinner second layer 504 disposed on a surface of first layer 502. Boot 304 may be arranged such that second layer 504 is in contact with a fluid 506, such as, for example, ocean water. In this arrangement, first layer 502 may be coupled to an electromechanical transducer (e.g., a sonar transducer), in order to directly transmit or receive vibrations to or from the electromechanical transducer. In other embodiments, boot 304 has multiple material layers with a first material layer in the stack being exposed to fluid 506 and a last material layer in the stack being coupled to the electromechanical transducer.

According to an embodiment, second layer 504 includes an added concentration by weight of copper-comprising particles. The copper-comprising particles may include cuprous oxide power. The copper-comprising particles may be added to the rubber material that forms the majority of second layer 504 during the mixing process before forming the material into a molded layer. That is, while the polymer material is being mixed, the copper-comprising particles can be added in, and the combination of the polymer material and the copper-comprising particles can continue to be mixed until the material is ready to be cured and formed into a particular shape. Thus, in one example, boot 304 is a single construction item but with copper particles proximate the outer surface that contacts fluid 506. A further example has the copper particles dispersed throughout second layer 504 or throughout boot 304.

In some embodiments, anywhere between 5% and 30% by weight of copper-comprising particles is added in second layer 504. In other such embodiments, anywhere between 0% and 50% by weight of copper-comprising particles is added in second layer 504. Second layer 504 may be less than 30% of the total thickness of boot 304 (e.g., the thickness of both first layer 502 and second layer 504), less than 50% of the total thickness of boot 304, or between about 20%-30% of the total thickness of boot 304. In other embodiments, second layer 504 is any portion of the total thickness of boot 304 (including an entire thickness of boot 304 in embodiments where layer 504 is the only material layer). In some embodiments, a total thickness of boot 304 that includes the thickness of both first layer 502 and second layer 504 is between about 0.15 inches and 0.25 inches. The total thickness of boot 304 may be application dependent, with higher operating frequencies using a boot with a lower total thickness. The addition of copper-comprising particles to second layer 504 helps to protect the surface of second layer 504 from bio-fouling caused by prolonged exposure to fluid 506. Additionally, the copper-comprising particles in second layer 504 enhance the thermal conductivity of boot 304, thus more effectively allowing boot 304 to transfer heat away from the electromechanical transducer as it operates.

According to some embodiments, the total thickness of boot 304 as described above is a thickness at a center point of boot 304 as it stretches over the opening of housing 302. The thickness of boot 304 may vary from the center point outwards to towards an edge of housing 302 around the opening.

According to some embodiments, the copper-comprising particles are added only to portions of second layer 504. For example, copper-comprising particles may be added in a checkerboard pattern across the surface of second layer 504. In another example, copper-comprising particles may be added in a bullseye pattern across the surface of second layer 504. Any other such patterns may be contemplated. In some embodiments, copper-comprising particles are applied in a random pattern across the surface of second layer 504. In some embodiments, some regions of second layer 504 are optimized to reduce marine growth by including a given concentration of the copper-comprising particles while other regions are optimized for acoustic performance by having no copper-comprising particles or a smaller concentration of copper-comprising particles.

According to some embodiments, other metal particles can be added to first layer 502 in addition to the copper-comprising particles in second layer 504. These other metal particles can include copper-comprising particles, such as the same copper-comprising particles of second layer 504. In some other examples, the metal particles in first layer 502 include one or more of titanium, stainless steel, aluminum or any iron-containing compound. Stainless steel may be advantageous for use in first layer 502 as it has excellent thermal conduction properties and is highly resistant to corrosion. In some embodiments, anywhere between 5% and 30% by weight of any of the aforementioned metal particles is added in first layer 502. In some embodiments, other metal particles are included in second layer 504 with the copper-comprising particles.

The inclusion of copper-comprising particles into a portion of boot 304 could lead to leaching of the copper from the boot material. Accordingly, in some embodiments, an inner layer of metal may be added to provide further protection from water intrusion after copper in second layer 504 has leached out. FIG. 6 illustrates the boot 304 of FIG. 5, with an inner layer 602 being added over first layer 502 to provide further corrosion resistance. As such, inner layer 602 may be a corrosively resistant metal like stainless steel or titanium. In some other embodiments, inner layer 602 is a polymer material, such as Teflon to name one example.

Inner layer 602 may be thinner than either first layer 502 or second layer 504. In some embodiments, the thickness of inner layer 602 is application dependent. Accordingly, the thickness of inner layer 602, in one example, is less than one tenth of the operating wavelength of the system. For example, sonar systems having a typical operating frequency between about 10 kHz and about 40 kHz have a smallest wavelength of about 3.8 cm (assuming a speed of sound through water of about 1,500 m/s). For such systems, inner layer 602 may have a thickness ranging between about 2 mm and about 4 mm.

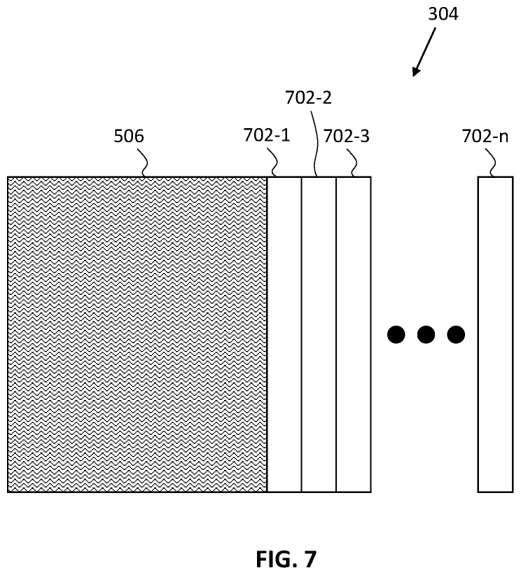

FIG. 7 illustrates another example of boot 304 having a multilayer configuration, according to an embodiment. Boot 304 includes a stack of n material layers 702-1 to 702-n. A first material layer 702-1 is in contact with fluid 506. A last material layer 702-n may have a surface that faces inwards towards one or more electromechanical transducers, such as sonar transducers.

According to an embodiment, any one of layers 702-1 to 702-n includes anywhere between 5% and 30% by weight, or anywhere between 0% and 50% by weight, of copper-comprising particles. Each of layers 702-1 to 702-n may include the same concentration of copper-comprising particles, or different concentrations of copper-comprising particles, including having no copper-comprising particles. In some embodiments, the concentration of copper-comprising particles increases with each successive layer. For example, layer 702-1 has a first concentration of copper-comprising particles, layer 702-2 has a second concentration of copper-comprising particles higher than the first concentration, layer 702-3 has a third concentration of copper-comprising particles higher than the second concentration, and so forth up through layer 702-n. In another example, layer 702-n has a first concentration of copper-comprising particles, layer 702-(n−1) has a second concentration of copper-comprising particles higher than the first concentration, layer 702-(n−2) has a third concentration of copper-comprising particles higher than the second concentration, and so forth up through layer 702-1.

In some embodiments, different metal particles may be added to different ones of layers 702-1 through 702-n. For example, some layers may include copper-comprising particles while other layers include stainless steel particles. The layers may alternate between layers having copper-comprising particles and layers having stainless steel particles. In some other embodiments, the layers alternate between layers having copper-comprising particles and layers having no added metal particles.

Numerous specific details have been set forth herein to provide a thorough understanding of the embodiments. It will be understood by an ordinarily-skilled artisan, however, that the embodiments may be practiced without these specific details. In other instances, well known operations, components and circuits have not been described in detail so as not to obscure the embodiments. It can be appreciated that the specific structural and functional details disclosed herein may be representative and do not necessarily limit the scope of the embodiments. In addition, although the subject matter has been described in language specific to structural features and/or methodological acts, it is to be understood that the subject matter defined in the appended claims is not necessarily limited to the specific features or acts described herein. Rather, the specific features and acts described herein are disclosed as example forms of implementing the claims.

### Further Example Embodiments

The following examples pertain to further embodiments, from which numerous permutations and configurations will be apparent.

Example 1 is a transducer system. The transducer system includes a housing having an opening, an electromechanical transducer within the housing, and an elastomeric boot over the opening. At least a portion of the elastomeric boot includes copper-comprising particles.

Example 2 includes the subject matter of Example 1, wherein the at least a portion of the elastomeric boot includes between 5% and 30% by weight copper-comprising particles.

Example 3 includes the subject matter of Example 1 or 2, wherein the copper-comprising particles comprise cuprous oxide.

Example 4 includes the subject matter of any one of Examples 1-3, wherein the at least a portion of the elastomeric boot is less than 50% of a total thickness of the elastomeric boot.

Example 5 includes the subject matter of any one of Examples 1-4, wherein the elastomeric boot has a laminar construction including a first material layer and a second material layer.

Example 6 includes the subject matter of Example 5, wherein the copper-comprising particles are included in the second material layer.

Example 7 includes the subject matter of Example 6, wherein the first material layer comprises particles that comprise a non-copper metal.

Example 8 includes the subject matter of any one of Examples 1-7, further comprising another material layer over an inner surface of the elastomeric boot, the inner surface facing inwards towards the housing.

Example 9 is a transducer system that includes a housing having an opening, an electromechanical transducer within the housing, and a bi-laminar boot over the opening. The bi-laminar boot has a first material layer and a second material layer. The second material layer of the bi-laminar boot includes copper-comprising particles.

Example 10 includes the subject matter of Example 9, wherein the second material layer includes between 5% and 30% by weight copper-comprising particles.

Example 11 includes the subject matter of Example 9 or 10, wherein the copper-comprising particles comprise cuprous oxide.

Example 12 includes the subject matter of any one of Examples 9-11, wherein a thickness of the second material layer is less than 50% of a total thickness of the bi-laminar boot.

Example 13 includes the subject matter of any one of Examples 9-12, wherein the second material layer faces away from the housing and the first material layer faces inward towards the housing.

Example 14 includes the subject matter of Example 13, further comprising another material layer over the first material layer facing inwards towards the housing.

Example 15 includes the subject matter of Example 14, wherein the another material layer comprises titanium, stainless steel, aluminum, or any iron-containing compound.

Example 16 includes the subject matter of any one of Examples 9-15, wherein the first material layer comprises particles that comprise a non-copper metal.

Example 17 is an electronic system configured for use in a marine environment that includes a housing having an opening, an electronic device within the housing, and an elastomeric boot over the opening. At least a portion of the elastomeric boot includes copper-comprising particles.

Example 18 includes the subject matter of Example 17, wherein the at least a portion of the elastomeric boot includes between 5% and 30% by weight copper-comprising particles.

Example 19 includes the subject matter of Example 17 or 18, wherein the copper-comprising particles comprise cuprous oxide.

Example 20 includes the subject matter of any one of Examples 17-19, wherein the at least a portion of the elastomeric boot is less than 50% of a total thickness of the elastomeric boot.

Example 21 includes the subject matter of any one of Examples 17-20, wherein the elastomeric boot has a laminar construction including a first material layer and a second material layer.

Example 22 includes the subject matter of Example 21, wherein the copper-comprising particles are included in the second material layer.

Example 23 includes the subject matter of Example 22, wherein the first material layer comprises particles that comprise a non-copper metal.

Example 24 includes the subject matter of any one of Examples 17-23, further comprising another material layer over an inner surface of the elastomeric boot, the inner surface facing inwards towards the housing.

What is claimed is:

1. A transducer system, comprising:
a housing having an opening;
an electromechanical transducer within the housing; and
an elastomeric boot over the opening, wherein at least a portion of the elastomeric boot includes copper-comprising particles.

2. The transducer system of claim 1, wherein the at least a portion of the elastomeric boot includes between 5% and 30% by weight copper-comprising particles.

3. The transducer system of claim 1, wherein the copper-comprising particles comprise cuprous oxide.

4. The transducer system of claim 1, wherein the at least a portion of the elastomeric boot is less than 50% of a total thickness of the elastomeric boot.

5. The transducer system of claim 1, wherein the elastomeric boot has a laminar construction including a first material layer and a second material layer.

6. The transducer system of claim 5, wherein the copper-comprising particles are included in the second material layer.

7. The transducer system of claim 6, wherein the first material layer comprises particles that comprise a non-copper metal.

8. The transducer system of claim 1, further comprising another material layer over an inner surface of the elastomeric boot, the inner surface facing inwards towards the housing.

9. A transducer system, comprising:
a housing having an opening;
an electromechanical transducer within the housing; and
a bi-laminar boot over the opening, the bi-laminar boot having a first material layer and a second material layer, wherein the second material layer of the bi-laminar boot includes copper-comprising particles.

10. The transducer system of claim 9, wherein the second material layer includes between 5% and 30% by weight copper-comprising particles.

11. The transducer system of claim 9, wherein the copper-comprising particles comprise cuprous oxide.

12. The transducer system of claim 9, wherein a thickness of the second material layer is less than 50% of a total thickness of the bi-laminar boot.

13. The transducer system of claim 9, wherein the second material layer faces away from the housing and the first material layer faces inward towards the housing.

14. The transducer system of claim 13, further comprising another material layer over the first material layer facing inwards towards the housing.

15. The transducer system of claim 14, wherein the another material layer comprises titanium, stainless steel, aluminum, or any iron-containing compound.

16. The transducer system of claim 9, wherein the first material layer comprises particles that comprise a non-copper metal.

17. An electronic system configured for use in a marine environment, comprising:
a housing having an opening;
an electronic device within the housing; and
an elastomeric boot over the opening, wherein at least a portion of the elastomeric boot includes copper-comprising particles.

18. The electronic system of claim 17, wherein the at least a portion of the elastomeric boot includes between 5% and 30% by weight copper-comprising particles.

19. The electronic system of claim 17, wherein the copper-comprising particles comprise cuprous oxide.

20. The electronic system of claim 17, wherein the at least a portion of the elastomeric boot is less than 50% of a total thickness of the elastomeric boot.

21. The electronic system of claim 17, wherein the elastomeric boot has a laminar construction including a first material layer and a second material layer.

22. The electronic system of claim 21, wherein the copper-comprising particles are included in the second material layer.

23. The electronic system of claim 22, wherein the first material layer comprises particles that comprise a non-copper metal.

24. The electronic system of claim 17, further comprising another material layer over an inner surface of the elastomeric boot, the inner surface facing inwards towards the housing.
